(19) United States
(12) Patent Application Publication
(10) Pub. No.: US 2026/0164862 A1
(43) Pub. Date: Jun. 11, 2026

(54) SEMICONDUCTOR LIGHT-EMITTING ELEMENT AND LIGHT-EMITTING DEVICE

(71) Applicant: QUANZHOU SANAN SEMICONDUCTOR TECHNOLOGY CO., LTD., quanzhou (CN)

(72) Inventors: Yongling LAN, quanzhou (CN); Guohua Zhang, quanzhou (CN); Zhongjie Yang, quanzhou (CN); Jingfeng Huang, quanzhou (CN); Chung-Ying Chang, quanzhou (CN)

(21) Appl. No.: 19/292,933

(22) Filed: Aug. 7, 2025

(30) Foreign Application Priority Data
Aug. 8, 2024 (CN) 202411086304.4

(51) Int. Cl. H10H 20/819; H10H 20/812; H10H 20/825

(52) U.S. Cl. CPC H10H 20/819; H10H 20/812; H10H 20/825

(57) ABSTRACT

A semiconductor light-emitting element and a light-emitting device are provided. An epitaxial structure of the semiconductor light-emitting element at least includes a first semiconductor layer structure, an active layer, and a second semiconductor layer structure stacked sequentially from bottom to top. The active layer includes: an Al_{y}Ga_{1-y}N barrier layer and an AlₓGa₁₋ₓN well layer, where 0<x<1, 0<y<1; and the second semiconductor layer structure comprises an AlₐGa₁₋ₐN material layer, where 0<a<1. As described above, the P-type layer is selected to be the AlₐGa₁₋ₐN material layer, thereby reducing the light absorption of the P-type layer. Additionally, the P-type layer can include an ohmic contact layer formed of an Al-free nitride material layer, and a thickness of the ohmic contact layer is controlled to be less than or equal to 10 nm to reduce the content of the P-type GaN material, thereby reducing the light absorption and improving the light extraction efficiency.

### CROSS-REFERENCE TO RELATED APPLICATION

This application claims priority to Chinese Patent Application No. 202411086304.4, filed on Aug. 8, 2024, which is herein incorporated by reference in its entirety.

### TECHNICAL FIELD

The disclosure relates to the technical field of semiconductor elements and devices, and more particularly to a semiconductor light-emitting element and a light-emitting device.

### BACKGROUND

The gallium nitride (GaN)-based light-emitting diode (LED), due to its high light-emitting efficiency, has been widely applied in various light source fields such as backlighting, illumination, automotive lighting, and decoration. From a technical perspective, further improving the light-emitting efficiency of LED chips remains a key focus of industry development. The light-emitting efficiency is mainly determined by two factors: the first factor is the radiative recombination efficiency of electrons and holes in the active region, namely the internal quantum efficiency; and the second factor is the light extraction efficiency.

For the nitride LED, in order to enhance its light-emitting efficiency, various epitaxial structures are commonly utilized to improve the internal quantum efficiency. One factor that affects the internal quantum efficiency is the light absorption characteristic of the gallium nitride material itself. To achieve good ohmic contact and high material quality, traditional gallium nitride epitaxial structures grow a thick P-type gallium nitride material for the P-type layer. However, the thick P-type gallium nitride material exhibits significant absorption of light less than or equal to 370 nanometers (nm), which severely affects the light output efficiency of the light-emitting element.

### SUMMARY

In response to the above shortcomings in the nitride LED in the related art, the disclosure provides a semiconductor light-emitting element and a light-emitting device to solve the above one or multiple problems by improving the material selection and the thickness setting of the P-type layer.

In a first aspect of the disclosure, a semiconductor light-emitting element is provided. The semiconductor light-emitting element at least includes an epitaxial structure. The epitaxial structure at least includes a first semiconductor layer structure, an active layer, and a second semiconductor layer structure which are stacked sequentially from bottom to top. The active layer includes: an Al_{y}Ga_{1-y}N barrier layer and an AlₓGa₁₋ₓN well layer, where Al represents aluminum, Ga represents gallium, N represents nitrogen, 0<x<1, 0<y<1; and the second semiconductor layer structure includes an AlₐGa₁₋ₐN material layer, where 0<a<1.

In an embodiment, a light-emitting device is provided. The light-emitting device includes the semiconductor light-emitting element provided by the disclosure.

As mentioned above, the semiconductor light-emitting element and the light-emitting device of the disclosure may have the following beneficial effects.

In the semiconductor light-emitting element of the disclosure, the active layer includes the Al_{y}Ga_{1-y}N barrier layer and the AlₓGa₁₋ₓN well layer, where 0<x<1, 0<y<1; and the second semiconductor layer structure includes an AlₐGa₁₋ₐN material layer, where 0<a<1. As described above, the P-type layer of the disclosure is selected to be the AlₐGa₁₋ₐN material layer, thereby reducing the light absorption of the P-type layer. Additionally, the P-type layer can include an ohmic contact layer formed of an Al-free nitride material layer, and a thickness of the ohmic contact layer is controlled to be less than or equal to 10 nm, so as to reduce the content of the P-type GaN material, thereby reducing the light absorption and improving the light extraction efficiency.

### BRIEF DESCRIPTION OF DRAWINGS

FIG. 1 illustrates a schematic structural diagram of a light-emitting element according to embodiment 1 of the disclosure.

FIG. 2 illustrates a schematic enlarged structural diagram of a part A illustrated in FIG. 1.

FIG. 3 illustrates a schematic enlarged structural diagram of the part A illustrated in FIG. 1 according to an optional embodiment of the disclosure.

FIG. 4 illustrates a schematic diagram of a concentration distribution of different elements in respective layers of an epitaxial structure in FIG. 1.

FIG. 5 illustrates a schematic diagram of a concentration distribution of different elements in respective layers of an epitaxial structure according to an optional embodiment of the disclosure.

FIG. 6 illustrates a schematic diagram of a light-emitting device according to embodiment 2 of the disclosure.

Description of reference signs: 100: light-emitting element; 110: substrate; 120: epitaxial structure; 121: first semiconductor layer structure; 122: active layer; 1221: barrier layer; 1222: well layer; 123: second semiconductor layer structure; 1231: first layer structure; 1232: second layer structure; 130: protective layer; 140: first electrode; 150: second electrode; 200: light-emitting device; 201: circuit substrate; 202: light-emitting element; H: thickness of second semiconductor layer structure; H1: thickness of first layer structure; H2: thickness of second layer structure.

### DETAILED DESCRIPTION OF EMBODIMENTS

The following specific examples illustrate embodiments of the disclosure, and those skilled in the art can easily understand other advantages and effects of the disclosure from the content disclosed in this specification. The disclosure can also be implemented or applied through different specific embodiments, and various details in this specification can be modified or changed based on different perspectives and applications without departing from the spirit of the disclosure.

The composition of each layer in the disclosure can be analyzed by any suitable means, such as secondary ion mass spectrometry (SIMS); the thickness of each layer can be analyzed by any suitable means, such as transmission electron microscopy (TEM) or scanning electron microscopy (SEM), to correlate with the depth positions of each layer on, for example, the SIMS profile.

In an embodiment of the disclosure, a semiconductor light-emitting element is provided. The semiconductor light-emitting element includes an epitaxial structure. The epitaxial structure includes a first semiconductor layer structure, an active layer, and a second semiconductor layer structure sequentially stacked from bottom to top. The active layer includes: an Al_{y}Ga_{1-y}N barrier layer and an AlₓGa₁₋ₓN well layer, where 0<x<1, 0<y<1; and the second semiconductor layer structure includes an AlₐGa₁₋ₐN material layer, where 0<a<1.

As described above, the second semiconductor layer structure of the epitaxial structure serves as a P-type layer and is selected to be the AlₐGa₁₋ₐN material layer, such that the light absorption of the P-type layer is reduced and the light-emitting performance of the light-emitting element is enhanced.

In an embodiment, the second semiconductor layer structure is a P-type doped layer, with a P-type dopant concentration greater than 1×10¹⁷ atoms per cubic centimeter (atom/cm³).

In an embodiment, a thickness of the second semiconductor layer structure is less than or equal to 200 nm.

In an embodiment, a thickness of the AlₐGa₁₋ₐN material layer is less than or equal to 200 nm.

By controlling the doping concentration of the P-type dopant in the second semiconductor layer structure and the thickness of the AlₐGa₁₋ₐN material layer, the second semiconductor layer structure may provide sufficient holes for recombination and ensure that the P-type dopant does not diffuse into the active layer, thus reducing the damage to the active layer and ensuring the efficiency of electron-hole recombination.

In an embodiment, a thickness of the AlₐGa₁₋ₐN material layer accounts for 60%-100% of a thickness of the second semiconductor layer structure.

By controlling the thickness proportion of the AlₐGa₁₋ₐN material layer in the second semiconductor layer structure, the content of the P-type gallium nitride material is minimized as much as possible, thereby reducing the light absorption of the P-type GaN material, and improving the light extraction efficiency of the light-emitting element.

In an embodiment, the second semiconductor layer structure includes an Al-free nitride material layer, and a thickness of the Al-free nitride material layer is less than or equal to 10 nm.

In an embodiment, the thickness of the Al-free nitride material layer is less than or equal to 5 nm.

In an embodiment, the thickness of the Al-free nitride material layer accounts for less than or equal to 10% of a thickness of the second semiconductor layer structure.

In an embodiment, a thickness of the AlₐGa₁₋ₐN material layer is greater than or equal to 120 nm.

In an embodiment, in the Al-free nitride material layer, a P-type dopant concentration is greater than 5×10¹⁷ atom/cm³.

In an embodiment, the Al-free nitride material layer is disposed on the AlₐGa₁₋ₐN material layer.

The second semiconductor layer structure may include the Al-free nitride material layer formed on the AlₐGa₁₋ₐN material layer, such as a GaN material layer or an indium gallium nitride (InGaN) material layer, and the thickness of the Al-free nitride material layer within the second semiconductor layer structure is controlled. The ohmic contact layer is formed by the Al-free nitride material layer, on one hand, good ohmic contact capability can still be ensured, and on the other hand, the content of the P-type GaN material can be minimized, thereby reducing the light absorption and improving light extraction efficiency.

In an embodiment, a thickness of the AlₐGa₁₋ₐN material layer is greater than the thickness of the Al-free nitride material layer.

In an embodiment, a thickness of the AlₐGa₁₋ₐN material layer is at least twice the thickness of the Al-free nitride material layer.

As described above, by controlling the position and thickness of the Al-free gallium nitride material layer, and strictly controlling the proportion of the Al-free gallium nitride material layer in the second semiconductor layer structure, the disclosure ensure that it does not cause significant light absorption, thereby guaranteeing the light extraction performance of the light-emitting element.

In an embodiment, a quantum well of the active layer is an indium (In)-free material layer.

In an embodiment, the second semiconductor layer structure is a P-type doped layer, and a P-type dopant of the P-type doped layer comprises magnesium atoms.

In an embodiment, a light-emitting wavelength of the active layer is in a range of 220-410 nm.

In an embodiment, a light-emitting wavelength of the active layer is in a range of 240-370 nm.

The P-type GaN material exhibits significant light absorption in the ultraviolet wavelength range, especially for a wavelength less than or equal to 370 nm, severely affecting the light extraction efficiency of the light-emitting element. Therefore, in an ultraviolet LED that emits radiation in the above wavelength range, increasing the proportion of the AlₐGa₁₋ₐN material layer in the second semiconductor layer structure can effectively reduce the light absorption and enhance the light extraction efficiency.

In an embodiment, the Al-free nitride material layer is a GaN material layer or an InGaN material layer.

In an embodiment, an Al content of the active layer is greater than or equal to 30%.

In an embodiment, in an entire range of thickness of the active layer, a P-type dopant concentration is less than 1×10¹⁹ atom/cm³.

In an embodiment, a light-emitting device is provided, the light-emitting device includes the semiconductor light-emitting element. The light-emitting device including the semiconductor light-emitting element has good light extraction efficiency and reliability.

### Embodiment 1

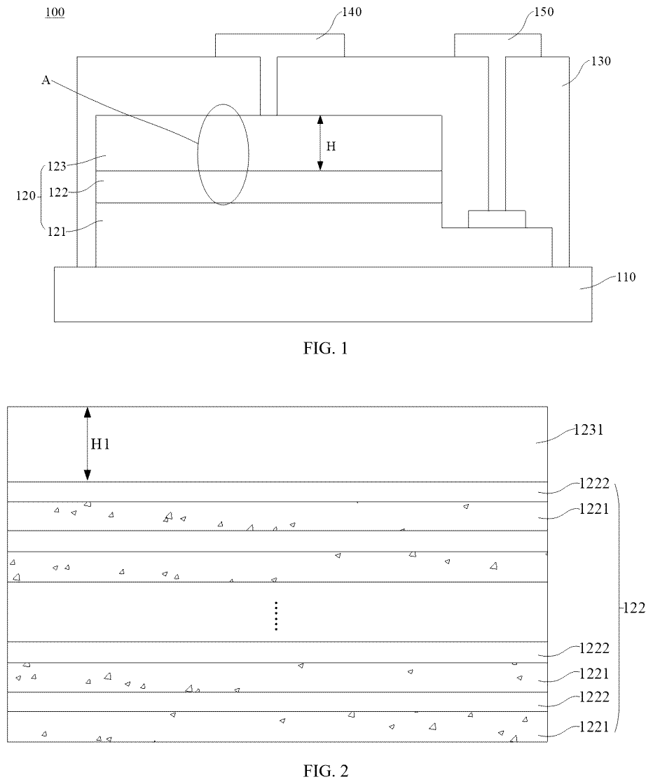

The embodiment provides a semiconductor light-emitting element 100 (also referred to as LED), as shown in FIG. 1. The light-emitting element 100 includes an epitaxial structure 120. The epitaxial structure 120 at least includes a first semiconductor layer structure 121, an active layer 122, and a second semiconductor layer structure 123 sequentially stacked from bottom to top. The epitaxial structure 120 can be any epitaxial structure capable of emitting light under the influence of voltage, such as an AlGaInN-based epitaxial structure, an AlGaN-based epitaxial structure, or an aluminum gallium indium phosphide (AlGaInP)-based epitaxial structure, etc. In this embodiment, the epitaxial structure 120 is exemplified as the AlGaN-based epitaxial structure capable of providing ultraviolet light. Optionally, the light-emitting element 100 can be a conventional, flip-chip, or vertical structure light-emitting element. In this embodiment, a flip-chip structured light-emitting element is used as an example for illustration.

The first semiconductor layer structure 121 can be an N-type layer, and correspondingly, the second semiconductor layer structure 123 can be a P-type layer; and the reverse is also feasible, that is, the first semiconductor layer structure 121 can be a P-type layer, and correspondingly, the second semiconductor layer structure 123 can be an N-type layer. In this embodiment, the first semiconductor layer structure 121 is exemplified as the N-type layer, and correspondingly, the second semiconductor layer structure 123 is the P-type layer.

In the embodiment, the N-type semiconductor layer is an N-type AlGaN layer, and the N-type AlGaN layer is configured to provide electrons and also serves as an ohmic contact layer when forming a first electrode 140 subsequently. The N-type AlGaN layer provides the electrons by doping with the N-type impurity, which can be elements such as silicon (Si), germanium (Ge), tin (Sn), selenium (Se), and tellurium (Te). In this embodiment, the Si is selected as the N-type impurity. The thickness of the N-type AlGaN layer is approximately in a range of 1-4 micrometers (μm), and the Si doping concentration ranges from 5×10¹⁸ atom/cm³ to 2×10²⁰ atom/cm³ to provide the electrons for radiative recombination. The N-type AlGaN layer is a layer with the highest N-type doping concentration in the epitaxial structure 120 and can be either a single-layer structure or a superlattice structure. Formed as a highly doped layer, the N-type AlGaN layer can reduce the contact resistance.

As shown in FIG. 1, the active layer 122 is formed on the first semiconductor layer structure 121. The active layer 122 is a region that provides light radiation through the recombination of electrons and holes. Different materials can be selected for the active layer 122 according to different light-emitting wavelengths. The active layer 122 can be a periodic structure of a single quantum well (SQW) or multiple quantum wells (MQW), composed of a quantum well layer 1222 and a barrier layer 1221. By adjusting the composition ratio of the semiconductor materials in the active layer 122, it is possible to achieve light emission at different wavelengths. In some embodiments, the active layer 122 is an In-free material layer, such as an AlGaN/AlGaN multi-quantum well structure with 5 -15 periods. Furthermore, the active layer 122 can be doped with the Si, with a doping concentration in a range of 1×10¹⁷ atom/cm³ to 1×10¹⁹ atom/cm³.

In the embodiment, as shown in FIG. 2, the active layer 122 includes: Al_{y}Ga_{1-y}N barrier layers and AlₓGa₁₋ₓN well layers, the number of the Al_{y}Ga_{1-y}N barrier layers is p, the number of the AlₓGa₁₋ₓN well layers is q, and the Al_{y}Ga_{1-y}N barrier layers and the AlₓGa₁₋ₓN well layers are alternately arranged; where 0<x<1, 0<y<1, 1≤p≤20, 0≤q≤20. Values of p and q can be the same or different. The barrier layers 1221 have a larger bandgap than the well layers 1222. The alternating arrangement of the barrier layers 1221 and the well layers 1222 in the active layer 122 can achieve the recombination of electrons and holes. The alternating arrangement of the Al_{y}Ga_{1-y}N barrier layers 1221 and the AlₓGa₁₋ₓN well layers 1222 ensures that the light emitted after the recombination of electrons and holes is ultraviolet light with a wavelength in a range of approximately 220 nm to 410 nm. Additionally, in the disclosure, both the barrier layers 1221 and the well layers 1222 in the active layer 122 are AlGaN material layers, with similar lattice constants and good crystal growth quality, and the active layer 122 has fewer dislocations or micro-pit defects. This also helps to prevent the diffusion of magnesium (Mg) atoms into the active layer 122. In optional embodiments, the Al content in the active layer 122 is controlled to be greater than or equal to 30%, and exemplarily greater than or equal to 50%. This control of the Al content and the selection of the material composition of the active layer 122 ensure effective recombination of electrons and holes, thereby guaranteeing the light emission performance of the ultraviolet LED and enabling the active layer 122 to emit the ultraviolet light with a wavelength around 300 nm. Optionally, the wavelength of the light emitted by the active layer 122 is in a range of 220 nm to 410 nm, and more specifically, 240 nm to 370 nm.

As shown in FIG. 1, in the embodiment, the second semiconductor layer structure 123 is the P-type layer that provides holes through doping with the P-type impurity, which can be Mg, zinc (Zn), calcium (Ca), strontium (Sr), and barium (Ba). In this embodiment, the Mg is selected as the P-type impurity. In optional embodiments, the second semiconductor layer structure 123 includes an Al-containing gallium nitride material layer. The thickness H of the second semiconductor layer structure 123 is less than or equal to 200 nm, and further, H≤100 nm. The thickness of the Al-containing gallium nitride material layer accounts for 60%-100% of the thickness of the second semiconductor layer structure 123, and further, 70%-100%, 80%-100%, 90%-100%, and 95%-100%. The thickness settings of the second semiconductor layer structure 123 and the proportion of the thickness of the Al-free gallium nitride material layer are designed to minimize the content of P-type gallium nitride material, thereby effectively reducing the light absorption of P-type gallium nitride material and improving the light extraction efficiency of the light-emitting element 100. The Mg doping concentration in the second semiconductor layer structure 123 is greater than or equal to 1×10¹⁷ atom/cm³, and further, the Mg doping concentration is greater than or equal to 1×10¹⁷ atom/cm³ and less than or equal to 1×10²¹ atom/cm³.

In an optional embodiment, the second semiconductor layer structure 123 is a single-material-layer structure. As shown in FIG. 2, the second semiconductor layer structure 123 includes a first layer structure 1231, and the first layer structure 1231 is an AlₐGa₁₋ₐN material layer, 0<a<1. In this embodiment, the thickness H1 of the first layer structure 1231 is less than or equal to 200 nm. The second semiconductor layer structure 123 consists of the first layer structure 1231 formed by the AlₐGa₁₋ₐN material layer, and the thickness H1 of the AlₐGa₁₋ₐN material layer 1231 accounts for 100% of the thickness H of the second semiconductor layer structure 123. Therefore, there is virtually no light absorption, which is beneficial for improving the light extraction efficiency of the light-emitting element 100. Additionally, the first layer structure 1231 is formed on the active layer 122 and is in direct contact with the active layer 122. Since the first layer structure 1231 is an Al-containing material layer, the first layer structure 1231 can to some extent prevent electrons from entering the second semiconductor layer structure 123. As a result, in the epitaxial structure 120 of the light-emitting element 100 of this embodiment, a separate electron blocking layer is not required, reducing the thickness of the epitaxial structure 120 and decreasing the light absorption. In some embodiments, when the thickness H of the second semiconductor layer structure 123 is 200 nm, the thickness H1 of the first layer structure 1231 is greater than or equal to 200 nm×60%=120 nm.

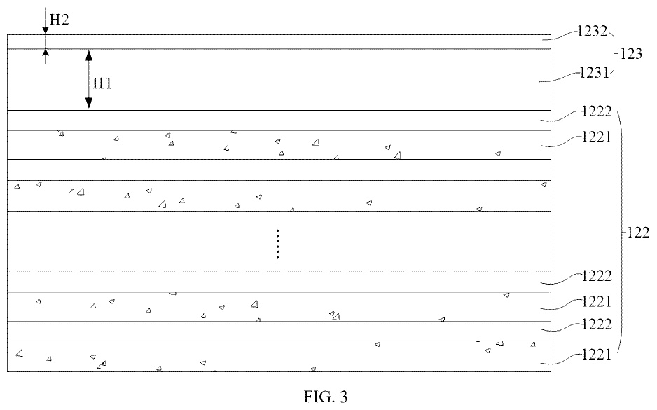

In an optional embodiment of the disclosure, the second semiconductor layer structure 123 is a multi-layer structure formed by different materials. Optionally, as shown in FIG. 3, the second semiconductor layer structure 123 may further include a second layer structure 1232, which is an Al-free nitride material layer. The Al-free nitride material layer can be a GaN material layer or an InGaN material layer, and the embodiments of the disclosure are not limited to these. The second layer structure 1232 is located on the first layer structure 1231, that is, the second layer structure 1232 is on a side of the first layer structure 1231 facing away from the active layer 122. In the second layer structure 1232, a doping concentration of the P-type dopant is greater than 5×10¹⁷ atom/cm³.

In the optional embodiment, to minimize the light absorption of the Al-free second layer structure 1232 as much as possible, the thickness H2 of the second layer structure 1232 is controlled to be less than the thickness H1 of the first layer structure 1231, and H1≥2H2. Further, H1≥3H2, H1≥4H2, or H1≥9H2. More specifically, the thickness H2 of the second layer structure 1232 is controlled to be less than or equal to 10 nm, and more specifically, H2 is less than or equal to 5 nm. The second layer structure 1232 is an Al-free material layer, which can enable the subsequently formed metal electrode to form a good ohmic contact with the second semiconductor layer structure 123, ensuring the electrical performance of the light-emitting element 100. Meanwhile, by controlling the thickness H2 of the second layer structure 1232 as described above, its light absorption is greatly reduced, thereby improving the light extraction efficiency of the light-emitting element 100. In some embodiments, the thickness H2 of the second layer structure 1232 accounts for less than or equal to 10% of the thickness H of the second semiconductor layer structure 123.

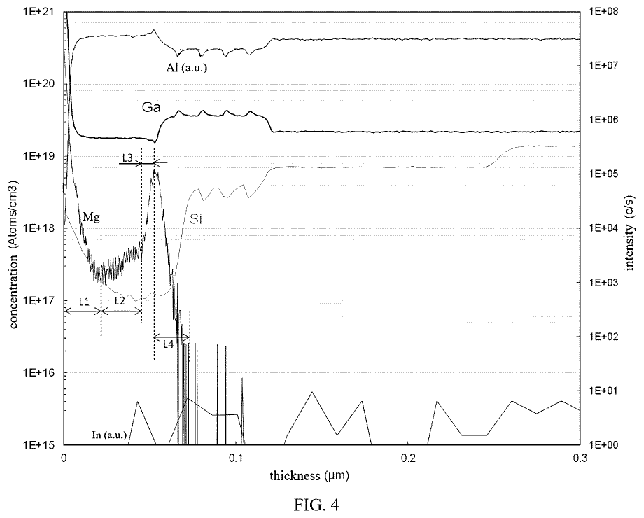

In the second semiconductor layer structure 123 having the structural features described above in this embodiment, the P-type dopant can have a variety of different diffusion profiles. As shown in FIG. 4, in an optional embodiment, taking the position at a depth of 0 μm on the horizontal axis in FIG. 4 as a reference point, that is, taking the upper surface of the second semiconductor layer structure 123 of the epitaxial structure 120 as the reference point, the thickness of the second semiconductor layer structure 123 is within a range of 0 nm to 60 nm from this reference point, and more specifically, within a range of 0 nm to 55 nm. The thickness of the active layer 122 is within a range of 50 nm to 130 nm from the reference point, and more specifically, within a range of 55 nm to 125 nm. Within the aforementioned depth range of the second semiconductor layer structure 123, along the diffusion direction of the P-type dopant, the P-type dopant concentration shows a trend of first decreasing and then increasing. The P-type dopant concentration first forms a first sharp drop zone L1, a gentle rise zone L2 at a rear end of the first sharp drop zone L1, and a steep rise zone L3 at a rear end of the gentle rise zone L2. The thickness range of the first sharp drop zone L1 is in a range of 0 nm to 20 nm, the thickness range of the gentle rise zone L2 is in a range of 15 nm to 45 nm, and the thickness range of the steep rise zone L3 is in a range of 40 nm to 55 nm. In the first sharp drop zone L1, the P-type dopant concentration is in a range of 1×10¹⁷ atom/cm³ to 1×10²¹ atom/cm³, that is, the P-type dopant concentration drops sharply from 1×10²¹ atom/cm³ to 1×10¹⁷ atom/cm³. After the first sharp drop zone L1, the P-type dopant shows a gradual upward trend, forming the gentle rise zone L2, where the P-type dopant concentration is in a range of 1×10¹⁷ atom/cm³ to 1×10¹⁸ atom/cm³, that is, the P-type dopant concentration gradually increases from 1×10¹⁷ atom/cm³ to 1×10¹⁸ atom/cm³. A concentration valley of the P-type dopant is formed between the first sharp drop zone L1 and the gentle rise zone L2, with the concentration valley located at a depth in a range of 15 nm to 25 nm in the second semiconductor layer structure 123. Subsequently, the concentration rises rapidly, forming the steep rise zone L3, where the P-type dopant concentration is in a range of 5×10¹⁷ atom/cm³ to 1×10¹⁹ atom/cm³, that is, the P-type dopant concentration rises rapidly from 5×10¹⁷ atom/cm³ to 1×10¹⁹ atom/cm³. After the steep rise zone L3, the Mg atoms enter the depth range of the active layer 122, and at this time, as shown in FIG. 4, the Mg atom concentration drops sharply, forming a second sharp drop zone L4. The slope of the decrease in the Mg atom concentration in the second sharp drop zone L4 is greater than the slope of the decrease in the Mg atom concentration in the first sharp drop zone L1 of the second semiconductor layer structure 123. In the second sharp drop zone L4, the P-type dopant concentration (i.e., the Mg atoms) is in a range of 1×10¹⁶ atom/cm³ to 1×10¹⁹ atom/cm³, that is, the P-type dopant concentration drops rapidly from 1×10¹⁹ atom/cm³ to 1×10¹⁶ atom/cm³. That is, in an entire range of thickness of the active layer, a P-type dopant concentration is less than 1×10¹⁹ atom/cm³. In the active layer 122 following the second semiconductor layer structure 123, there is almost no P-type dopant diffused in, such as the Mg atoms.

The P-type dopant concentration control in the second semiconductor layer structure 123 ensures that there is a sufficient amount of P-type dopant in the second semiconductor layer structure 123 to guarantee an adequate supply of holes. At the same time, it ensures that there are virtually no Mg atoms in the aforementioned depth range of the active layer 122, thereby reducing the damage to the active layer 122 and ensuring the efficiency of electron-hole recombination.

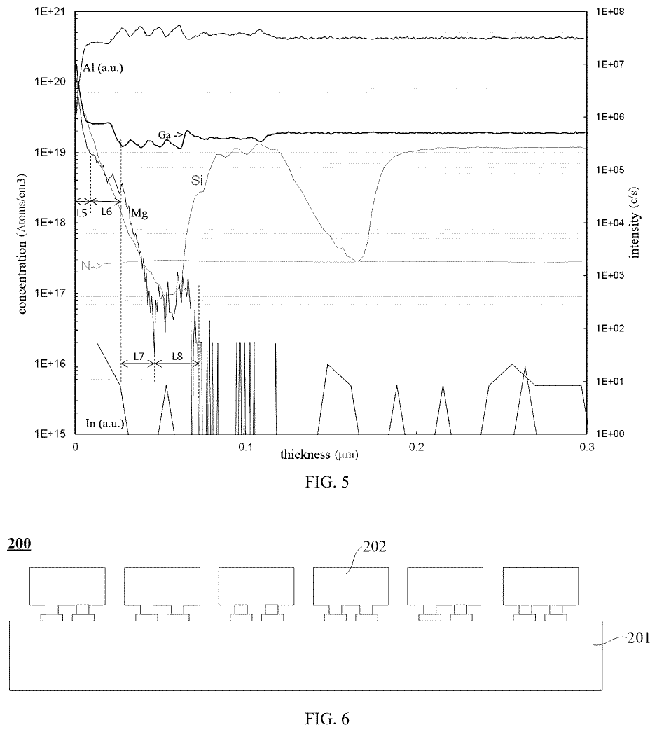

In an optional embodiment, as shown in FIG. 5, taking the position at a depth of 0 μm on the horizontal axis in the figure as a reference point, that is, taking the upper surface of the second semiconductor layer structure 123 of the epitaxial structure 120 as the reference point, the thickness of the second semiconductor layer structure 123 is in a range of 0 nm to 80 nm from this reference point, and more specifically, within a range of 0 nm to 70 nm. The thickness of the active layer 122 is in a range of 60 nm to 130 nm from this reference point, and more specifically, in a range of 65 nm to 120 nm. In the aforementioned depth range of the second semiconductor layer structure 123, along the diffusion direction of the P-type dopant, the P-type dopant concentration forms a third sharp drop zone L5, followed by a gentle drop zone L6 at a rear end of the third sharp drop zone L5. In the third sharp drop zone L5, the P-type dopant concentration is in a range of 1×10¹⁹ atom/cm³ to 1×10²¹ atom/cm³, that is, in the third sharp drop zone L5, the P-type dopant concentration drops rapidly from 1×10²¹ atom/cm³ to 1×10¹⁹ atom/cm³. In the gentle drop zone L6, the P-type dopant concentration is in a range of 1×10¹⁸ atom/cm³ to 1×10¹⁹ atom/cm³, that is, in the gentle drop zone L6, the P-type dopant concentration drops gradually from 1×10¹⁹ atom/cm³ to 1×10¹⁸ atom/cm³. Referring to FIG. 5, the third sharp drop zone L5 is formed within the thickness range of 0 nm to 10 nm of the second semiconductor layer structure 123, and the gentle drop zone L6 is formed within the thickness range of 10 nm to 50 nm of the second semiconductor layer structure 123.

In the optional embodiment, after the gentle drop zone L6, the P-type dopant concentration forms a fourth sharp drop zone L7, followed by a buffer zone L8 located after the fourth sharp drop zone L7. As shown in FIG. 5, the slope of the decrease in the P-type dopant concentration in the fourth sharp drop zone L7 is greater than the slope of the decrease in the P-type dopant concentration in the third sharp drop zone L5. Specifically, in the fourth sharp drop zone L7, the P-type dopant concentration is in a range of 1×10¹⁶ atom/cm³ to 5×10¹⁸ atom/cm³, that is, in the fourth sharp drop zone L7, the P-type dopant concentration drops sharply from 5×10¹⁸ atom/cm³ to 1×10¹⁶ atom/cm³. In the buffer zone L8, the P-type dopant concentration is in a range of 1×10¹⁶ atom/cm³ and 5×10¹⁷ atom/cm³, that is, in the buffer zone L8, the P-type dopant concentration drops gradually from 5×10¹⁷ atom/cm³ to 1×10¹⁶ atom/cm³.

As described above, by controlling the diffusion characteristics of the Mg atoms in the second semiconductor layer structure 123, the active layer 122 following the second semiconductor layer structure 123 virtually contains no diffused P-type dopants, which effectively reduces the impact of Mg atoms on the MQW, and improves the MQW quality, thus ensuring the recombination efficiency of electrons and holes in the active layer 122. This is conducive to enhancing the light-emitting efficiency.

As shown in FIG. 1, the light-emitting element 100 further includes a protective layer 130 formed on the surface of the epitaxial structure 120. The protective layer 130 covers the upper surface of the epitaxial structure 120 and, optionally, also covers the sidewalls of the epitaxial structure 120 to protect the epitaxial structure 120 from damage caused by moisture, dust, and other impurities. An electrode structure is formed on the epitaxial structure 120. The protective layer 130 also covers the sidewalls of the electrode structure, or partially covers the upper surface of the electrode structure to protect the electrode structure while exposing the upper surface of the electrode structure to facilitate subsequent bonding of the light-emitting element 100. As shown in FIG. 1, the electrode structure includes a first electrode 140 and a second electrode 150. The first electrode 140 is electrically connected to the first semiconductor layer structure 121, for example, forming an ohmic contact with the N-type AlGaN layer. The second electrode 150 is electrically connected to the second semiconductor layer structure 123, for example, through the ohmic contact layer 1232.

Referring to FIG. 1, the light-emitting element 100 of this embodiment may further include a substrate 110, with the epitaxial structure 120 disposed thereon. The epitaxial structure 120 can be directly grown on the substrate 110, or can be grown on a growth substrate and then transferred to the substrate 110. The substrate 110 can be an insulating substrate or a conductive substrate. In optional embodiments, the substrate 110 is a growth substrate used for the epitaxial growth of the semiconductor epitaxial layers, including sapphire (aluminum oxide, Al₂O₃), silicon carbide (SiC) substrates, and Si substrates, etc. The substrate 110 includes a first surface and a second surface that are arranged opposite to each other. The substrate 110 is a patterned substrate with a micro-pattern on the first surface. This patterned substrate is conducive to the growth of the epitaxial structure 120 and can reduce the number of dislocations in the epitaxial structure 120, thereby improving the crystal quality of the epitaxial structure 120.

In an optional embodiment, the first semiconductor layer structure 121 may further include a base layer located between the N-type AlGaN layer and the substrate. The base layer includes a U-type AlN layer and a U-type AlGaN layer. The AlN layer and the AlGaN layer can effectively relieve the stress generated during the growth of the N-type AlGaN layer, which is conducive to obtaining the epitaxial structure 120 with high crystal quality. It can be understood that, in order to achieve light emission from the substrate side for the flip-chip LED of this embodiment, a reflective structure, such as a distributed Bragg reflector (DBR) structure, is also formed on the side of the P-type semiconductor layer. The aforementioned protective layer 130 can also be an insulating material layer with reflective properties.

### Embodiment 2

An embodiment provides a light-emitting device. As shown in FIG. 6, the light-emitting device 200 includes a substrate 201 and light-emitting elements 202 disposed on the substrate 201. Each of the light-emitting elements 202 can be the light-emitting element 100 provided by the embodiment 1. The substrate 201 can be a package substrate, or a circuit substrate for connecting to an external power source. The light-emitting device 200 can be formed as a sterilization and disinfection device.

The above embodiments are only illustrative of the principles and effects of the disclosure, and are not intended to limit the disclosure. Anyone familiar with this technology may modify or alter the above embodiments without departing from the spirit and scope of the disclosure. Therefore, all equivalent modifications or changes made by those skilled in the art without departing from the spirit and technical ideas disclosed in the disclosure should still be covered by the claims of the disclosure.

What is claimed is:

1. A semiconductor light-emitting element, comprising:
an epitaxial structure, at least comprising: a first semiconductor layer structure, an active layer, and a second semiconductor layer structure sequentially stacked from bottom to top;
wherein the active layer comprises: an Al_{y}Ga_{1-y}N barrier layer and an AlₓGa₁₋ₓN well layer, where Al represents aluminum, Ga represents gallium, N represents nitrogen, 0<x<1, 0<y<1; and
wherein the second semiconductor layer structure comprises an AlₐGa₁₋ₐN material layer, where 0<a<1.

2. The semiconductor light-emitting element as claimed in claim 1, wherein the second semiconductor layer structure is a P-type doped layer, with a P-type dopant concentration greater than 1×10¹⁷ atoms per cubic centimeter (atom/cm³).

3. The semiconductor light-emitting element as claimed in claim 1, wherein a thickness of the second semiconductor layer structure is less than or equal to 200 nanometers (nm).

4. The semiconductor light-emitting element as claimed in claim 1, wherein a thickness of the AlₐGa₁₋ₐN material layer is less than or equal to 200 nm.

5. The semiconductor light-emitting element as claimed in claim 1, wherein a thickness of the AlₐGa₁₋ₐN material layer accounts for 60%-100% of a thickness of the second semiconductor layer structure.

6. The semiconductor light-emitting element as claimed in claim 1, wherein the second semiconductor layer structure comprises an Al-free nitride material layer, and a thickness of the Al-free nitride material layer is less than or equal to 10 nm.

7. The semiconductor light-emitting element as claimed in claim 6, wherein the thickness of the Al-free nitride material layer is less than or equal to 5 nm.

8. The semiconductor light-emitting element as claimed in claim 6, wherein the thickness of the Al-free nitride material layer accounts for less than or equal to 10% of a thickness of the second semiconductor layer structure.

9. The semiconductor light-emitting element as claimed in claim 1, wherein a thickness of the AlₐGa₁₋ₐN material layer is greater than or equal to 120 nm.

10. The semiconductor light-emitting element as claimed in claim 6, wherein in the Al-free nitride material layer, a P-type dopant concentration is greater than 5×10¹⁷ atom/cm³.

11. The semiconductor light-emitting element as claimed in claim 6, wherein the Al-free nitride material layer is disposed on the AlₐGa₁₋ₐN material layer.

12. The semiconductor light-emitting element as claimed in claim 6, wherein a thickness of the AlₐGa₁₋ₐN material layer is greater than the thickness of the Al-free nitride material layer.

13. The semiconductor light-emitting element as claimed in claim 6, wherein a thickness of the AlₐGa₁₋ₐN material layer is at least twice the thickness of the Al-free nitride material layer.

14. The semiconductor light-emitting element as claimed in claim 1, wherein a quantum well of the active layer is an indium (In)-free material layer.

15. The semiconductor light-emitting element as claimed in claim 1, wherein the second semiconductor layer structure is a P-type doped layer, and a P-type dopant of the P-type doped layer comprises magnesium atoms.

16. The semiconductor light-emitting element as claimed in claim 1, wherein a light-emitting wavelength of the active layer is in a range of 220-410 nm.

17. The semiconductor light-emitting element as claimed in claim 6, wherein the Al-free nitride material layer is a GaN material layer or an InGaN material layer.

18. The semiconductor light-emitting element as claimed in claim 1, wherein an Al content of the active layer is greater than or equal to 30%.

19. The semiconductor light-emitting element as claimed in claim 1, wherein in an entire range of thickness of the active layer, a P-type dopant concentration is less than 1×10¹⁹ atom/cm³.

20. A light-emitting device, comprising: a circuit substrate, and light-emitting elements disposed on the circuit substrate; wherein the light-emitting elements comprise the semiconductor light-emitting element as claimed in claim 1.
